(19) United States
(12) Patent Application Publication
(10) Pub. No.: US 2026/0186307 A1
(43) Pub. Date: Jul. 2, 2026

(54) DISPLAY DEVICE, HEAD MOUNTED DISPLAY INCLUDING DISPLAY DEVICE, AND ELECTRONIC DEVICE INCLUDING DISPLAY DEVICE

(71) Applicant: Samsung Display Co., LTD., Yongin-si (KR)

(72) Inventors: IN-SUN KIM, Yongin-si (KR); JUNMO IM, Yongin-si (KR)

(21) Appl. No.: 19/279,402

(22) Filed: Jul. 24, 2025

(30) Foreign Application Priority Data
Dec. 26, 2024 (KR) 10-2024-0197698

(51) Int. Cl. G02B 27/01

(52) U.S. Cl. CPC G02B 27/0176; G02B 27/0172

(57) ABSTRACT

A display device includes first to third display panels. The first display panel includes a first substrate. First and second openings are defined in the first display layer. The second display panel overlaps the first opening. The third display panel overlaps the second opening . The resolution of each of the second display panel and the third display panel is higher than the resolution of the first display panel. The first substrate defines first region and second regions therein. A first length, which is a distance from the first region to one of the first and second openings, is smaller than a second length, which is a distance from the second region to one of the first and second openings. A surface roughness of the first substrate in the first region is greater than a surface roughness of the first substrate in the second region.

This application claims priority to Korean Patent Application No. 10-2024-0197698, filed on December 26, 2024, and all the benefits accruing therefrom under 35 U.S.C. §119, the content of which in its entirety is herein incorporated by reference.

### BACKGROUND

### 1. Field

The disclosure relates to a display device, a head-mounted display including the display device, and an electronic device including the display device. Specifically, the disclosure pertains to a display device including display panels with different resolutions, a head-mounted display including such a display device, and an electronic device including the display device.

### 2. Description of the Related Art

A head-mounted display typically includes a display device, which in turn includes a display panel that emits light. The visual field of a user utilizing a head-mounted display is divided into a central region and a peripheral region.

In conventional head-mounted displays, a display panel is disposed only for a portion corresponding to the central region of the visual field, while no separate display panel is provided for portions corresponding to the peripheral region. Consequently, images are not provided to the portions corresponding to the peripheral region of the visual field, resulting in dizziness to the user and lowered attention in the displayed image.

### SUMMARY

A feature of the disclosure is to provide a display device, a head-mounted display, and an electronic device in which a high-resolution display panel is disposed in a portion corresponding to the central region of the field of view, and a low-resolution display panel is disposed in portions corresponding to the peripheral region of the field of view, thereby reducing the user’s experience of dizziness and enhancing the sense of immersion for the displayed image.

A display device in an embodiment of the disclosure may include a first display panel, a second display panel, and a third display panel. The first display panel may include a first substrate and a first display layer. The first substrate may include a first material, and the first display layer may include a first light-emitting diode. The first display layer may define a first opening and a second opening therein. The second display panel may overlap the first opening and include a second substrate and a second display layer. The second substrate may include a second material different from the first material, and the second display layer may include a second light-emitting diode. The third display panel may overlap the second opening and include a third substrate and a third display layer. The third substrate may include a third material different from the first material, and the third display layer may include a third light-emitting diode. The resolutions of each of the second display panel and the third display panel may be higher than the resolution of the first display panel. The first substrate may define a first region and a second region therein. A first length from the first region to one of the first opening and the second opening may be smaller than a second length from the second region to one of the first opening and the second opening. The surface roughness of the first substrate in the first region may be greater than the surface roughness of the first substrate in the second region.

In an embodiment of the disclosure, the first display panel may further include a first circuit layer disposed between the first substrate and the first display layer. The first circuit layer may include a first semiconductor pattern, a first gate insulation layer, a first gate pattern, a first inter-insulation layer, a first source-drain pattern, and a first via layer. The first semiconductor pattern may be disposed above the first substrate and may include a semiconductor material. The first gate insulation layer may cover the first semiconductor pattern. The first gate pattern may be disposed above the first gate insulation layer, and at least a portion of the first gate pattern may overlap the first semiconductor pattern. The first inter-insulation layer may cover the first gate pattern. The first source-drain pattern may be disposed on the first inter-insulation layer, and at least a portion of the first source-drain pattern may be electrically connected to the first semiconductor pattern. The first via layer may cover at least a portion of the first source-drain pattern. The first circuit layer may define a third opening and a fourth opening therein. The third opening may overlap the first opening in a first direction. The fourth opening may overlap the second opening in the first direction.

In an embodiment of the disclosure, a portion of the first via layer that overlaps the first region of the first substrate may be carbonized.

The display device in an embodiment of the disclosure may further include an adhesive layer, which attaches each of the second and third display panels to the first display panel. A portion of the adhesive layer may be disposed between the first substrate of the first display panel and the second display layer of the second display panel. Another portion of the adhesive layer may be disposed between the first substrate of the first display panel and the third display layer of the third display panel.

The display device in an embodiment of the disclosure may further include a filling member, which may comprise a transparent material and may be disposed in the first and second openings. The first via layer may define a fifth opening therein, and the fifth opening may be disposed between the third opening or the fourth opening and the first light-emitting diode. The first display layer may further include a first pixel defining layer disposed on the first via layer. The first pixel defining layer may define a first light-emitting diode opening and a sixth opening therein. The first light-emitting diode may be disposed in the first light-emitting diode opening, and the sixth opening may overlap the fifth opening in the first direction.

In an embodiment of the disclosure, the first substrate may define a seventh opening and an eighth opening therein. The seventh opening may overlap the first opening in the first direction, and the eighth opening may overlap the second opening in the first direction.

In an embodiment of the disclosure, the second display layer may be disposed within at least a portion of the first, third, and seventh openings, and the third display layer may be disposed within at least a portion of the second, fourth, and eighth openings.

In an embodiment of the disclosure, a second direction may intersect the first direction. The second display panel and the third display panel may include a second circuit layer and a third circuit layer, respectively. A third length of the second display layer measured along the second direction, may be smaller than a fourth length of the second circuit layer measured along the second direction. A fifth length of the third display layer measured along the second direction may be smaller than a sixth length of the third circuit layer measured along the second direction.

The display device in an embodiment of the disclosure may further include an adhesive layer, which may attach each of the second and third display panels to the first display panel. A portion of the adhesive layer may be disposed between the first substrate of the first display panel and the second circuit layer of the second display panel, and another portion of the adhesive layer may be disposed between the first substrate of the first display panel and the third circuit layer of the third display panel.

In an embodiment of the disclosure, the second display panel and the third display panel may include a second circuit layer and a third circuit layer, respectively. The second circuit layer of the second display panel may be disposed in at least a portion of the first, third, and seventh openings, and the third circuit layer of the third display panel may be disposed in at least a portion of the second, fourth, and eighth openings.

In an embodiment of the disclosure, a second direction may intersect the first direction. The second display panel and the third display panel may include a second circuit layer and a third circuit layer, respectively. A seventh length of the second circuit layer measured along the second direction may be smaller than an eighth length of the second substrate measured along the second direction. A ninth length of the third circuit layer measured along the second direction may be smaller than a tenth length of the third substrate measured along the second direction.

The display device in an embodiment of the disclosure may further include an adhesive layer, which may attach each of the second and third display panels to the first display panel. A portion of the adhesive layer may be disposed between the first substrate of the first display panel and the second substrate of the second display panel, and another portion of the adhesive layer may be disposed between the first substrate of the first display panel and the third substrate of the third display panel.

In an embodiment of the disclosure, the first material may be polyimide (“PI”), and the second and third materials may each be silicon (Si).

The display device in an embodiment of the disclosure may further include a fourth substrate and an adhesive layer. The fourth substrate may be disposed below the first, second, and third display panels, and the adhesive layer may be disposed on the fourth substrate. The first, second, and third display panels may be disposed on the adhesive layer.

A head-mounted display in an embodiment of the disclosure may include a display device and a head-mounted apparatus. The display device may emit light, and the head-mounted apparatus may include a frame to which the display device is coupled. The display device may include a first display panel, a second display panel, and a third display panel. The first display panel may include a first substrate and a first display layer. The first substrate may include a first material, and the first display layer may include a first light-emitting diode. The first display layer may define a first opening and a second opening therein. The second display panel may overlap the first opening and may include a second substrate and a second display layer. The second substrate may include a second material different from the first material. The second display layer may include a second light-emitting diode. The third display panel may overlap the second opening and may include a third substrate and a third display layer. The third substrate may include a third material different from the first material, and the third display layer may include a third light-emitting diode. The resolution of each of the second display panel and the third display panel may be higher than the resolution of the first display panel.

In an embodiment of the disclosure, the first substrate may define a first region and a second region therein. A first length from the first region to one of the first opening and the second opening may be smaller than a second length from the second region to one of the first opening and the second opening. The surface roughness of the first substrate in the first region may be greater than the surface roughness of the first substrate in the second region.

In an embodiment of the disclosure, the first display panel may further include a first circuit layer, which may be disposed between the first substrate and the first display layer. The first circuit layer may include a first semiconductor pattern, a first gate insulation layer, a first gate pattern, a first inter-insulation layer, a first source-drain pattern, and a first via layer. The first semiconductor pattern may be disposed above the first substrate and may include a semiconductor material. The first gate insulation layer may cover the first semiconductor pattern. The first gate pattern may be disposed above the first gate insulation layer, and at least a portion of the first gate pattern may overlap the first semiconductor pattern. The first inter-insulation layer may cover the first gate pattern. The first source-drain pattern may be disposed on the first inter-insulation layer, and at least a portion of the first source-drain pattern may be electrically connected to the first semiconductor pattern. The first via layer may cover at least a portion of the first source-drain pattern. The first circuit layer may define a third opening and a fourth opening therein. The third opening may overlap the first opening in a first direction, and the fourth opening may overlap the second opening in the first direction. A portion of the first via layer overlapping the first region of the first substrate may be carbonized.

In an embodiment of the disclosure, the display device may further include a filling member disposed in the first and second openings. The filling member may include a transparent material. The first via layer may define a fifth opening therein, and the fifth opening may be disposed between the third opening or the fourth opening and the first light-emitting diode. The first display layer may further include a first pixel defining layer, which may define a first light-emitting diode opening and a sixth opening therein. The first light-emitting diode may be disposed in the first light-emitting diode opening, and the sixth opening may overlap the fifth opening in the first direction.

In an embodiment of the disclosure, the first substrate may define a seventh opening and an eighth opening therein. The seventh opening may overlap the first opening in the first direction, and the eighth opening may overlap the second opening in the first direction. The second display layer may be disposed in at least a portion of the first, third, and seventh openings, and the third display layer may be disposed in at least a portion of the second, fourth, and eighth openings.

An electronic device in an embodiment of the disclosure may include a display device configured to emit light. The display device may include a first display panel, a second display panel, and a third display panel. The first display panel may include a first substrate and a first display layer. The first substrate may include a first material, and the first display layer may include a first light-emitting diode. The first display layer may define a first opening and a second opening therein. The second display panel may overlap the first opening and may include a second substrate and a second display layer. The second substrate may include a second material different from the first material, and the second display layer may include a second light-emitting diode. The third display panel may overlap the second opening and may include a third substrate and a third display layer. The third substrate may include a third material different from the first material, and the third display layer may include a third light-emitting diode. The resolution of each of the second display panel and the third display panel may be higher than the resolution of the first display panel.

The first substrate may define a first region and a second region therein. A first length from the first region to one of the first opening and the second opening may be shorter than a second length from the second region to one of the first opening and the second opening. The surface roughness of the first substrate in the first region may be greater the surface roughness of the first substrate that in the second region.

With the embodiments of the disclosure, it is possible to provide a display device, a head-mounted display, and an electronic device by arranging a high-resolution display panel in the region corresponding to the central field of view and arranging a low-resolution display panel in the region corresponding to the peripheral field of view, thereby reducing the user’s experience of dizziness and enhancing the sense of immersion for the displayed image.

### BRIEF DESCRIPTION OF THE DRAWINGS

These and/or other features will become apparent and more readily appreciated from the following description of the embodiments, taken in conjunction with the accompanying drawings in which:

FIG. 1A illustrates a block diagram of an embodiment of an electronic device according to the disclosure;

FIG. 1B illustrates an embodiment of an electronic device according to the disclosure;

FIG. 1C is an enlarged view of an embodiment of a head-mounted display according to the disclosure;

FIG. 1D illustrates an embodiment of a user wearing the head-mounted display of FIG. 1C;

FIG. 2A illustrates an embodiment of a head-mounted display according to the disclosure;

FIG. 2B is an enlarged view of the display device of the head-mounted display shown in FIG. 2A;

FIG. 3A illustrates a cross-sectional view of an embodiment of a display device according to the disclosure;

FIG. 3B is an enlarged view of a portion of the first display panel;

FIG. 3C is an enlarged view of a portion of the second display panel;

FIG. 3D is an enlarged view of a portion of the third display panel; and

FIGS. 4A through 4G illustrate an embodiment of display devices according to the disclosure.

### DETAILED DESCRIPTION

References will now be made in detail to illustrative embodiments, of which examples are illustrated in the accompanying drawings, where like reference numerals refer to like elements throughout. The embodiments may have a variety of forms and permutations, but the disclosure shall by no means be construed as being limited to the described embodiments. Rather, the disclosure shall be construed to encompass all forms, permutations, equivalents and substitutes covered by the technical ideas and scope of the disclosure. Accordingly, the embodiments are merely described below, by referring to the drawing figures, to explain features of the disclosure.

Like or identical reference numerals refer to like or identical elements. Moreover, in the accompanying drawings, the thicknesses, ratios, and dimensions of the elements may not be to exact scale and may have been exaggerated for priority to effective explanation of the technical features associated with these elements. As such, the disclosure shall not be restricted to the thicknesses, ratios, dimensions, etc. illustrated in the drawings. The term “and/or” shall include the combination of a plurality of listed items or any of the plurality of listed items that may be defined by relevant elements.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

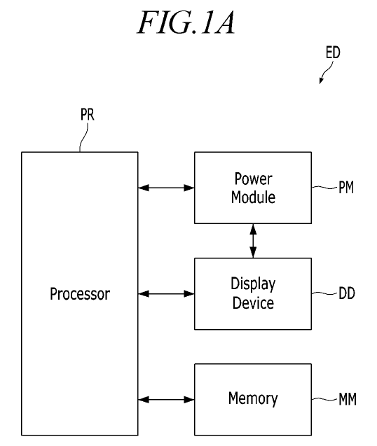

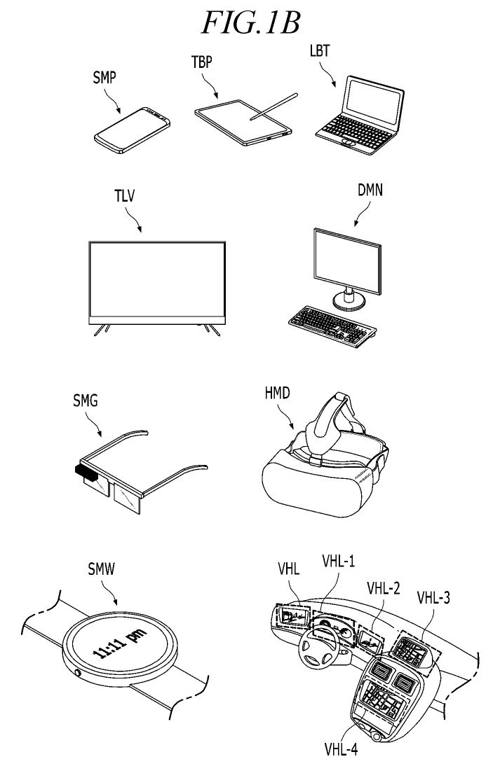

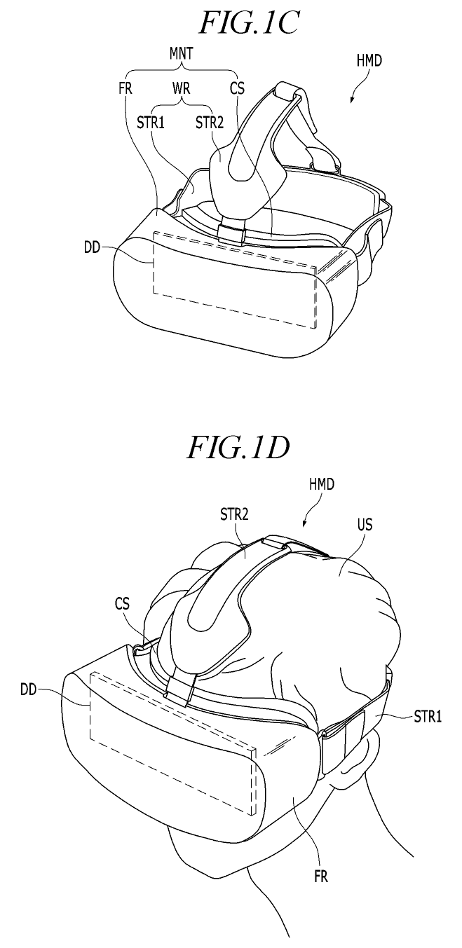

FIG. 1A illustrates an embodiment of a block diagram of an electronic device ED according to the disclosure. FIG. 1B illustrates an embodiment of the electronic devices ED according to the disclosure.

A display device DD in an embodiment of the disclosure may be applied to various electronic devices ED. An electronic device ED in an embodiment may include the above-described display device DD and may further include modules or devices with supplementary functions in addition to the display device DD.

Referring to FIG. 1A, the electronic device ED in an embodiment of the disclosure may include a display device DD, a processor PR, a memory MM, and a power module PM.

The processor PR may include at least one of a central processing unit (“CPU”), an application processor (“AP”), a graphics processing unit (“GPU”), a communication processor (“CP”), an image signal processor (“ISP”), and a controller.

The memory MM may have data and information stored therein for the operation of the processor PR or the display device DD. When the processor PR executes an application stored in the memory MM, at least one of an image data signal and an input control signal may be transferred to the display device DD, which may then process the received signals and output image information.

The power module PM may include a power supply module, such as a power adapter or a battery device, and a power conversion module configured to convert the power supplied by the power supply module into power desired for the operation of the electronic device ED.

At least one of the above-described components of the electronic device ED may be included within the display device DD according to the above-described embodiment. Additionally, predetermined individual modules included functionally within a single module may be provided within the display device DD while other individual modules may be provided outside the display device DD. In an embodiment, the electronic device ED may include the display device DD, and the processor PR, memory MM, and power module PM may be provided as other devices within the electronic device ED but not within the display device DD, for example.

Referring to FIG. 1B, the display device DD in an embodiment of the disclosure may be applied to various electronic devices ED such as image-display electronic devices, including smartphones SMP, tablet personal computers (“PCs”) TBP, laptops LBT, TVs TLV, and desktop monitors DMN, wearable electronic devices, including smart glasses SMG, head-mounted displays HMD, and smartwatches SMW, and vehicle electronic devices VHL to VHL9-4, including instrument panels, center fascias, dashboards equipped with center information displays (“CIDs”), or room mirror displays.

FIG. 1C is an enlarged view of an embodiment of a head-mounted display HMD according to the disclosure. FIG. 1D illustrates an embodiment of a user US wearing the head-mounted display HMD shown in FIG. 1C.

The electronic device ED in an embodiment of the disclosure may be a head-mounted display HMD. The head-mounted display HMD may include a head-mounted apparatus MNT and a display device DD.

The head-mounted apparatus MNT may include a frame FR, a wearing unit WR, and a cushion unit CS. The frame FR may be worn on the head of the user US. The display device DD may be coupled to the frame FR.

Various functional components may be housed within the frame FR. In an embodiment, an accelerometer (not shown) may be housed within the frame FR. The accelerometer may detect the movement of the user US and transmit corresponding signals to the display device DD, for example. Accordingly, the display device DD may provide images corresponding to the changes in the user's gaze. Additionally, a proximity sensor (not shown) may be housed within the frame FR. The proximity sensor may determine whether the user US has worn the head-mounted apparatus MNT.

The wearing unit WR may be coupled to the frame FR and may allow the user US to readily wear the head-mounted display HMD. The wearing unit WR may include a first strap STR1 and a second strap STR2.

The first strap STR1 may be worn around the circumference of the user's head. The first strap STR1 may secure the frame FR to the user US by maintaining close contact between the frame FR and the user's head.

The second strap STR2 may connect the frame FR and the first strap STR1 along the upper portion of the user's head. The second strap STR2 may prevent the frame FR from slipping downward from the user's head. Additionally, the second strap STR2 may distribute the weight of the frame FR, thereby improving the user's wearing comfort. In an embodiment of the disclosure, the second strap STR2 may be omitted.

In FIGS. 1C and 1D, the first strap STR1 and the second strap STR2 are illustrated that their lengths are adjustable, but this is merely one of embodiments and does not limit the first strap STR1 and the second strap STR2 of the disclosure. In other embodiments, the first strap STR1 and the second strap STR2 may have elastic properties, and/or their lengths may not be adjustable.

The wearing unit WR only needs to allow the user US to easily wear the head-mounted display HMD. Thus, the structure of the wearing unit WR is not limited to those illustrated in FIGS. 1C and 1D. In an embodiment, in other embodiments of the disclosure, the wearing unit WR may take the form of a helmet coupled to the frame FR or a temple piece of eyeglasses coupled to the frame FR, for example.

The cushion unit CS may be disposed between the frame FR and the head of the user US. The cushion unit CS may include an elastic material. The cushion unit CS may include at least one of a polymer resin and a sponge. The cushion unit CS may aid in ensuring close contact between the frame FR and the user US, thereby enhancing the user's wearing comfort. The cushion unit CS may be detachable from the frame FR. In another embodiment of the disclosure, the cushion unit CS may be omitted.

In an embodiment, the polymer resin may include at least one of polyurethane, polycarbonate, polypropylene, and polyethylene. The sponge may be formed by foaming at least one of rubber liquid, urethane-based materials, and acrylic-based materials, for example. However, these examples do not limit the composition of the cushion unit CS.

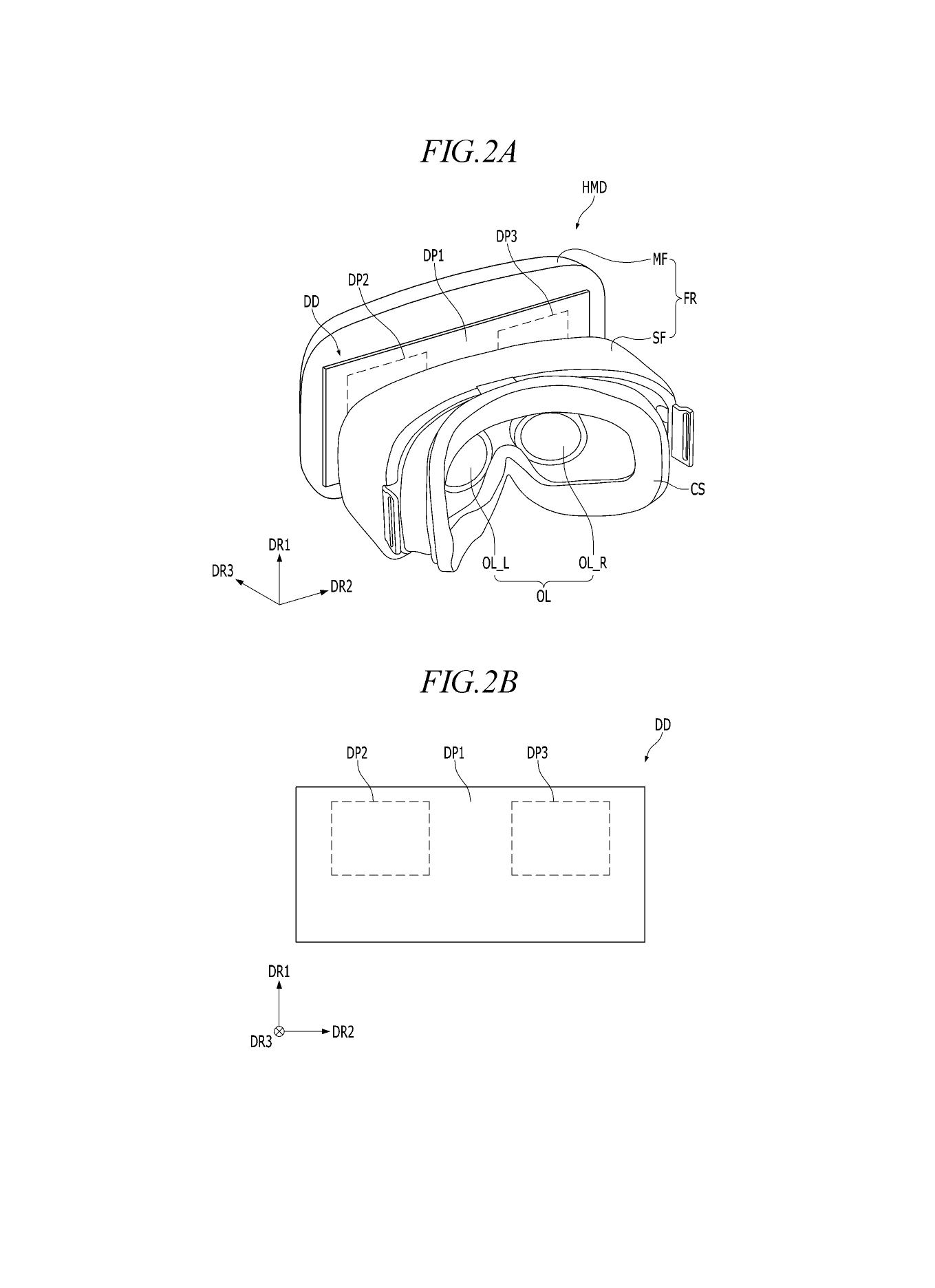

FIG. 2A illustrates an embodiment of a head-mounted display HMD according to the disclosure. FIG. 2B is an enlarged view of the display device DD shown in FIG. 2A.

The display device DD may extend along a first direction DR1 and a second direction DR2. The second direction DR2 may intersect the first direction DR1. A third direction DR3 may intersect both the first direction DR1 and the second direction DR2.

Referring to FIG. 2A, the head-mounted display HMD may include a head-mounted apparatus MNT and a display device DD. In an embodiment, the head-mounted display HMD may further include an optical system OL. The optical system OL may be disposed in the main frame MF. The optical system OL may magnify an image provided from the display device DD. The optical system OL may be spaced apart from the display device DD in the third direction DR3. The optical system OL may include a right-eye optical system OL_R and a left-eye optical system OL_L. The left-eye optical system OL_L may provide a magnified image to a left pupil of the user US, and the right-eye optical system OL_R may provide a magnified image to a right pupil of the user US. The left-eye optical system OL_L and the right-eye optical system OL_R may be spaced apart from each other in the second direction DR2. In an embodiment, a distance between the right-eye optical system OL_R and the left-eye optical system OL_L may be adjusted based on a distance between two eyes of the user US. In such an embodiment, a distance between the optical system OL and the display device DD may be adjusted based on a visual acuity of the user US. In an embodiment, the optical system OL may be a convex aspheric lens.

The field of view of a user US using the head-mounted display HMD may be divided into a central region and a peripheral region. In conventional head-mounted displays, a display panel is disposed only in the region corresponding to the central field of view, while no separate display panel is provided for the region corresponding to the peripheral field of view. Consequently, the peripheral region does not display images, causing dizziness for the user US and reducing immersion in the displayed content. Specifically, the central field of view may correspond to a range within 110 degrees from the center of the user's field of view, while the peripheral field of view may correspond to a range beyond 110 degrees from the center of the user's field of view.

The disclosure proposes a display device DD, a head-mounted display HMD, and an electronic device ED that include separate display panels arranged in the region corresponding to the peripheral field of view, thereby reducing dizziness experienced by the user US and improving immersion in the displayed content.

Referring to FIG. 2B, the display device DD may emit light. The display device DD may include a first display panel DP1, a second display panel DP2, and a third display panel DP3. The second display panel DP2 and the third display panel DP3 may correspond to the peripheral field of view, while the first display panel DP1 may correspond to the central field of view. The resolutions of the second display panel DP2 and the third display panel DP3 may each be higher than the resolution of the first display panel DP1.

In an embodiment of the disclosure, each of the second display panel DP2 and the third display panel DP3 may be one of an organic light-emitting display panel using organic light-emitting elements, a micro-light emitting diode (“micro-LED”) display panel using micro light-emitting diodes, a quantum dot display panel including quantum dot light-emitting diodes (“QLEDs”), a liquid crystal on silicon substrate (“LCoS”) display panel, an organic light-emitting device on silicon substrate (“OLEDoS”) display panel, and an light-emitting diode on silicon substrate (“LEDoS”) display panel. The first display panel DP1 may have a lower resolution and lower power consumption than the second display panel DP2 and the third display panel DP3.

The frame FR may include a main frame MF and a sub-frame SF. The display device DD may be disposed between the main frame MF and the sub-frame SF.

The sub-frame SF may cover at least a portion of a rear surface of the display device DD. The sub-frame SF may be coupled to the main frame MF and may form the exterior of the head-mounted apparatus MNT.

Although it is illustrated in FIG. 2A that the main frame MF and the sub-frame SF are separable from each other, this is merely one of embodiments and does not limit the disclosure. In an embodiment, the main frame MF and the sub-frame SF may be provided as an integrated structure, that is, the main frame MF and the sub-frame SF may not be separable, for example.

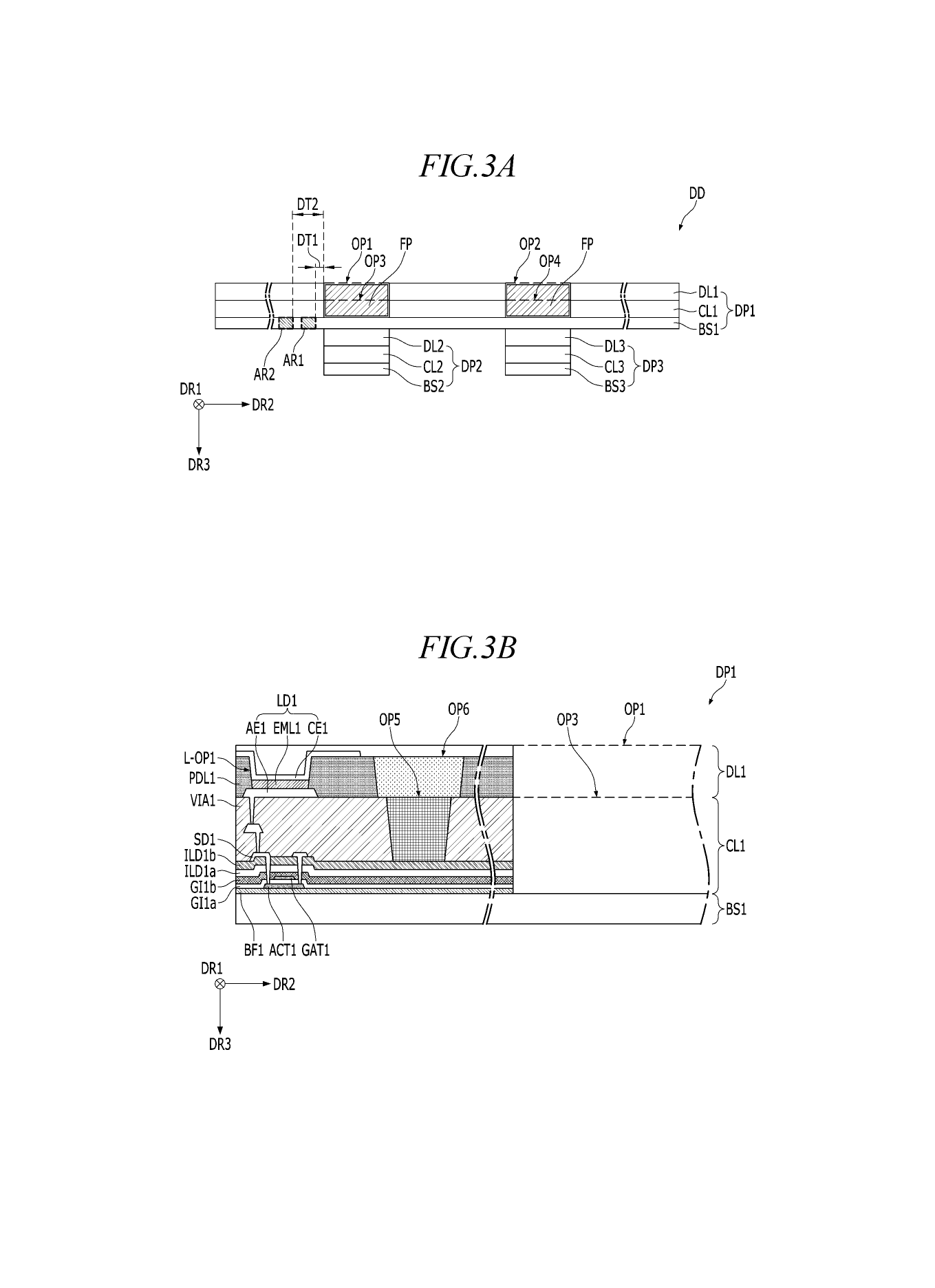

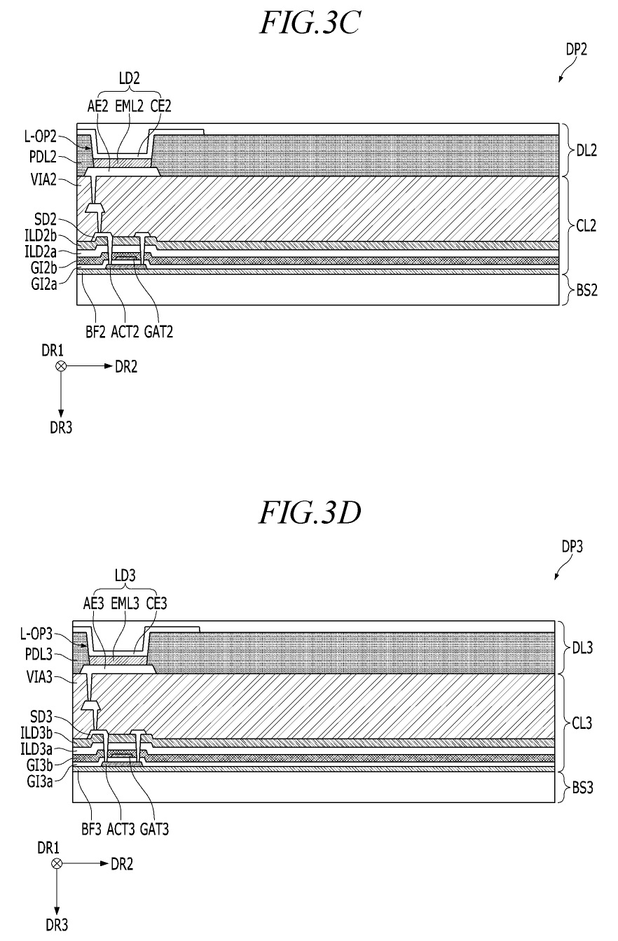

FIG. 3A illustrates a cross-sectional view of an embodiment of the display device DD according to the disclosure.

The first display panel DP1 may include a first substrate BS1, a first circuit layer CL1, and a first display layer DL1.

The first substrate BS1 may define a first region AR1 and a second region AR2 therein. In an embodiment of the disclosure, the surface roughness of the first substrate BS1 in the first region AR1 may be greater than that of the first substrate BS1 in the second region AR2. Specifically, during the laser-based removal process in the Hole In Active Area (“HIAA”) method, a portion of the first substrate BS1 may experience an increase in surface roughness.

The first display layer DL1 may define a first opening OP1 and a second opening OP2 therein. In an embodiment of the disclosure, the first opening OP1 and the second opening OP2 may be defined using the HIAA method.

Through this method, the dead space or bezel occurring between the first display panel DP1 and the second display panel DP2, as well as between the first display panel DP1 and the third display panel DP3, may be reduced to 2 millimeters (mm) or less.

Additionally, by employing the HIAA method, the display device DD of the disclosure may be efficiently implemented by combining existing display panels without the need for developing new display panels.

In an embodiment of the disclosure, a first length DT1 may refer to the distance from the first region AR1 to one of the first opening OP1 and the second opening OP2. A second length DT2 may refer to the distance from the second region AR2 to one of the first opening OP1 and the second opening OP2. The first length DT1 may be shorter than the second length DT2.

The display device DD in an embodiment of the disclosure may further include a filling member FP. The filling member FP may include a transparent material and may be disposed in the first opening OP1 and the second opening OP2. The filling member FP may include at least one of a transparent resin, a thermosetting agent, or a ultra violet (“UV”)-curable agent.

In an embodiment of the disclosure, the first circuit layer CL1 may define a third opening OP3 and a fourth opening OP4 therein. The third opening OP3 may overlap the first opening OP1 in the first direction DR1, and the fourth opening OP4 may overlap the second opening OP2 in the first direction DR1.

The second display panel DP2 may include a second substrate BS2, a second circuit layer CL2, and a second display layer DL2. The second display panel DP2 may overlap the first opening OP1.

The third display panel DP3 may overlap the second opening OP2. The third display panel DP3 may include a third substrate BS3, a third circuit layer CL3, and a third display layer DL3.

In an embodiment of the disclosure, the first substrate BS1 may include a first material, the second substrate BS2 may include a second material, and the third substrate BS3 may include a third material. The second material and the third material may each be different from the first material. In an embodiment, the first material may be polyimide (“PI”), and the second material and the third material may each be silicon (Si), for example.

FIG. 3B is an enlarged view of a portion of the first display panel DP1. Referring to FIG. 3B, the first circuit layer CL1 may be disposed between the first substrate BS1 and the first display layer DL1.

The first circuit layer CL1 may include a first buffer layer BF1, a first semiconductor pattern ACT1, a first gate insulation layer (GI1a and GI1b), a first gate pattern GAT1, a first inter-insulation layer ILD1, a first source-drain pattern SD1, and a first via layer VIA1.

The first buffer layer BF1 may be disposed between the first substrate BS1 and the first semiconductor pattern ACT1. The first buffer layer BF1 may include at least one of an inorganic material and an organic material. In an embodiment, the first buffer layer BF1 may include at least one of silicon nitride, silicon oxynitride, silicon oxide, titanium oxide, aluminum oxide, and an acrylic-based organic material. In an embodiment, the first buffer layer BF1 may be omitted, for example.

The first semiconductor pattern ACT1 may be disposed above the first substrate BS1 and may include a semiconductor material. In an embodiment of the disclosure, the semiconductor material may include at least one of an amorphous silicon semiconductor, a polycrystalline silicon semiconductor, a metal oxide semiconductor, a crystalline oxide semiconductor, and an amorphous oxide semiconductor. In an embodiment, the oxide semiconductor may include at least one of indium-tin oxide (“ITO”), indium-gallium-zinc oxide (“IGZO”), zinc oxide (ZnO), indium-zinc oxide (IZnO), zinc-indium oxide (“ZIO”), indium oxide (InO), titanium oxide (TiO), indium-zinc-tin oxide (“IZTO”), and zinc-tin oxide (“ZTO”), for example.

The first gate insulation layer (GI1a and GI1b) may include a first lower gate insulation layer GI1a and a first upper gate insulation layer GI1b.

The first lower gate insulation layer GI1a may cover the first semiconductor pattern ACT1. The first lower gate insulation layer GI1a may be disposed on the first substrate BS1. The first lower gate insulation layer GI1a may include an organic insulating material and/or an inorganic insulating material. In an embodiment, the first lower gate insulation layer GI1a may include at least one of polysiloxane, silicon nitride, silicon oxide, silicon oxynitride, polyacrylate-based compounds, polyimide-based compounds, fluorine-based carbon compounds, and benzocyclobutene compounds, for example.

The first gate pattern GAT1 may be disposed on the first lower gate insulation layer GI1a. At least a portion of the first gate pattern GAT1 may overlap the first semiconductor pattern ACT1. The first gate pattern GAT1 may include a metal material. In an embodiment, the first gate pattern GAT1 may include at least one of gold (Au), silver (Ag), aluminum (Al), molybdenum (Mo), chromium (Cr), titanium (Ti), nickel (Ni), neodymium (Nd), and copper (Cu), for example.

The first upper gate insulation layer GI1b may be disposed on the first lower gate insulation layer GI1a. The first upper gate insulation layer GI1b may cover the first gate pattern GAT1. The first upper gate insulation layer GI1b may include an organic material and/or an inorganic insulating material. In an embodiment, the first upper gate insulation layer GI1b may include at least one of polysiloxane, silicon nitride, silicon oxide, silicon oxynitride, polyacrylate-based compounds, polyimide-based compounds, fluorine-based carbon compounds, and benzocyclobutene compounds the first upper gate insulation layer GI1b may further include at least one additional layer including an insulating material, for example.

The first inter-insulation layer ILD1 may include a first lower inter-insulation layer ILD1a and a first upper inter-insulation layer ILD1b.

The first lower inter-insulation layer ILD1a may cover the first upper gate insulation layer GI1b. The first lower inter-insulation layer ILD1a may include an insulating material. In an embodiment, the first lower inter-insulation layer ILD1a may include at least one of polysiloxane, silicon nitride, silicon oxide, and silicon oxynitride, for example.

The first upper inter-insulation layer ILD1b may cover the first lower inter-insulation layer ILD1a. The first upper inter-insulation layer ILD1b may include an insulating material. In an embodiment, the first upper inter-insulation layer ILD1b may include at least one of polysiloxane, silicon nitride, silicon oxide, and silicon oxynitride, for example.

The first source-drain pattern SD1 may be disposed on the first inter-insulation layer ILD1. At least a portion of the first source-drain pattern SD1 may be electrically connected to the first semiconductor pattern ACT1. The first source-drain pattern SD1 may include a metal material. In an embodiment, the first source-drain pattern SD1 may include at least one of gold (Au), silver (Ag), aluminum (Al), molybdenum (Mo), chromium (Cr), titanium (Ti), nickel (Ni), neodymium (Nd), and copper (Cu), for example.

The first via layer VIA1 may cover at least a portion of the first source-drain pattern SD1. In an embodiment, the first via layer VIA1 may define a fifth opening OP5 therein. The fifth opening OP5 may be disposed between one of the third opening OP3 and the fourth opening OP4 and a first light-emitting diode LD1.

The filling member FP may be formed using at least one of a hot air curing technique, a heated plate curing technique, or a UV curing technique. During the manufacturing process in which the filling member FP is formed, outgassing may be generated and may travel along a layer including or consisting of an organic material, potentially affecting the first light-emitting diode LD1. The fifth opening OP5 and a sixth opening OP6 may each prevent the outgassing from affecting the first light-emitting diode LD1.

In an embodiment of the disclosure, the portion of the first via layer VIA1 overlapping the first region AR1 of the first substrate BS1 may be carbonized. Specifically, while a portion of the first display panel DP1 is removed using a laser during the HIAA process, a portion of the first via layer VIA1 may be carbonized.

The first display layer DL1 may include the first light-emitting diode LD1 and a first pixel defining layer PDL1.

The first pixel defining layer PDL1 may be disposed on the first via layer VIA1. The first pixel defining layer PDL1 may define a first light-emitting diode opening L-OP1 define therein. The first light-emitting diode LD1 may be disposed in the first light-emitting diode opening L-OP1.

The first light-emitting diode LD1 may include a first anode electrode AE1, a first light-emitting layer EML1, and a first cathode electrode CE1. The first anode electrode AE1 may be electrically connected to the first semiconductor pattern ACT1 through the first source-drain pattern SD1. In an embodiment, the first light-emitting diode LD1 may be, but not limited to, an organic light-emitting diode (“OLED”).

In an embodiment of the disclosure, the first pixel defining layer PDL1 may have the sixth opening OP6 therein. The sixth opening OP6 may overlap the fifth opening OP5 in the first direction DR1.

FIG. 3C is an enlarged view of a portion of the second display panel DP2. Referring to FIG. 3C, the second circuit layer CL2 may include a second buffer layer BF2, a second semiconductor pattern ACT2, a second gate insulation layer (GI2a and GI2b), a second gate pattern GAT2, a second inter-insulation layer (ILD2a and ILD2b), a second source-drain electrode SD2, and a second via layer VIA2.

The second display layer DL2 may include a second light-emitting diode LD2 and a second pixel defining layer PDL2. The second pixel defining layer PDL2 may define a second light-emitting diode opening L-OP2 define therein. In an embodiment, the second light-emitting diode LD2 may further include a second anode electrode AE2, a second light-emitting layer EML2, and a second cathode electrode CE2. The second anode electrode AE2 may be electrically connected to the second semiconductor pattern ACT2 through the second source-drain pattern SD2. In an embodiment, the second light-emitting diode LD2 may be, but not limited to, an OLED. Other descriptions of the second circuit layer CL2 and the second display layer DL2 are substantially the same as those described in FIG. 3C and thus will be omitted.

FIG. 3D is an enlarged view of a portion of the third display panel DP3. Referring to FIG. 3D, the third circuit layer CL3 may include a third buffer layer BF3, a third semiconductor pattern ACT3, a third gate insulation layer (GI3a and GI3b), a third gate pattern GAT3, a third inter-insulation layer (ILD3a and ILD3b), a third source-drain electrode SD3, and a third via layer VIA3.

The third display layer DL3 may include a third light-emitting diode LD3 and a third pixel defining layer PDL3. The third pixel defining layer PDL3 may define a third light-emitting diode opening L-OP3 define therein. In an embodiment, the third light-emitting diode LD3 may further include a third anode electrode AE3, a third light-emitting layer EML3, and a third cathode electrode CE3. The third anode electrode AE3 may be electrically connected to the third semiconductor pattern ACT3 through the third source-drain pattern SD3. In an embodiment, the third light-emitting diode LD3 may be, but not limited to, an OLED. Other descriptions of the third circuit layer CL3 and the third display layer DL3 are substantially the same as those described in FIG. 3C and thus will be omitted.

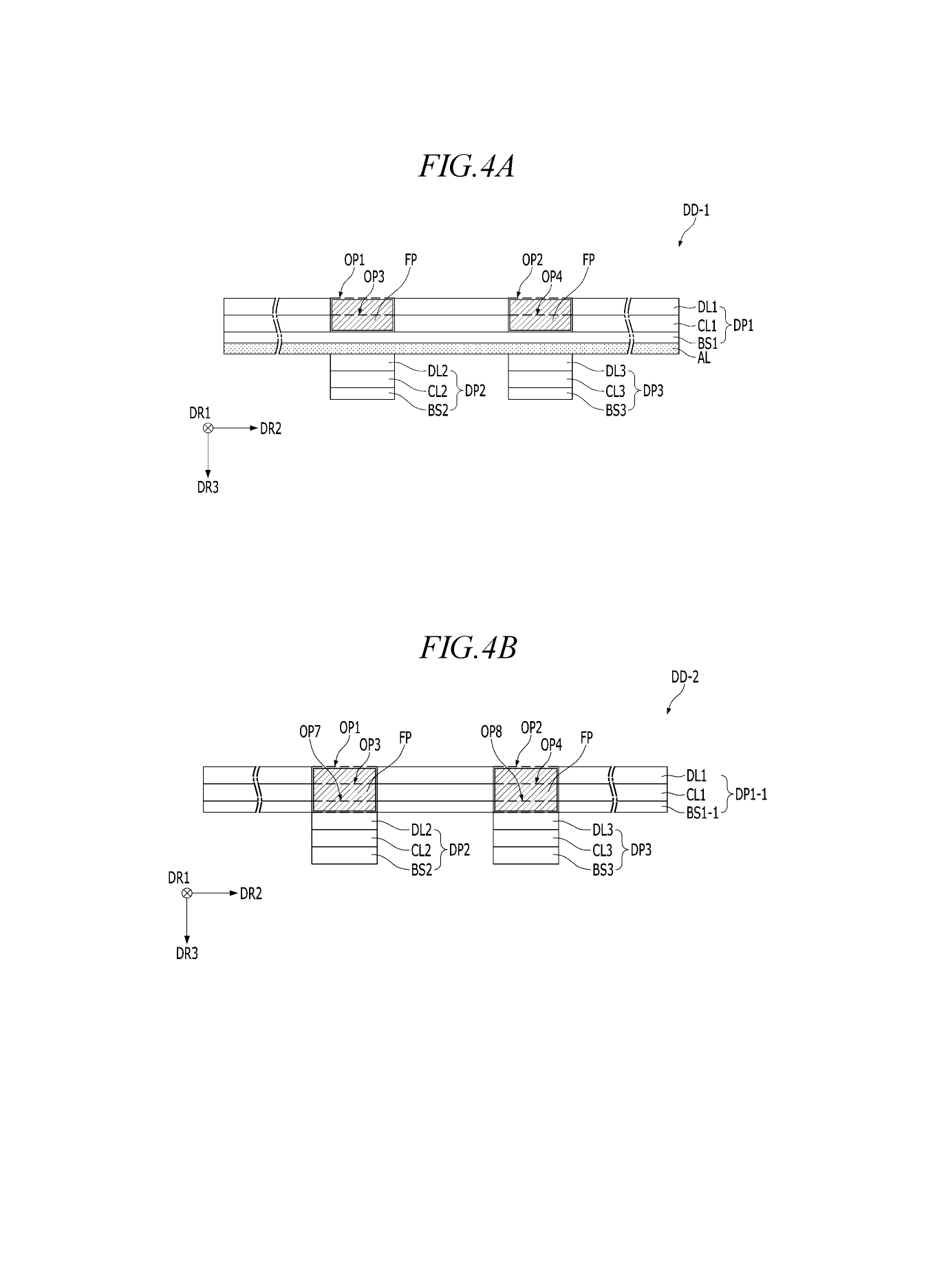

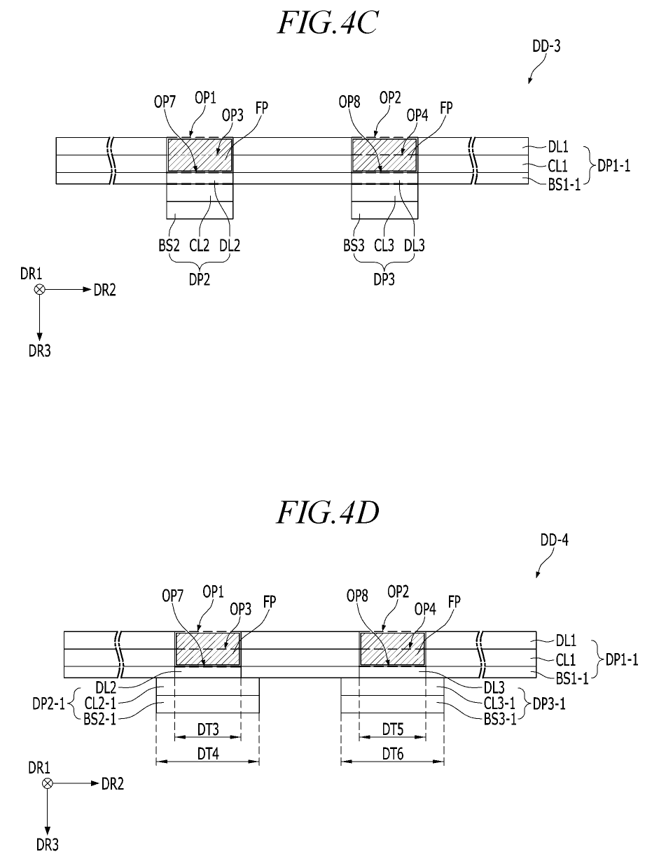

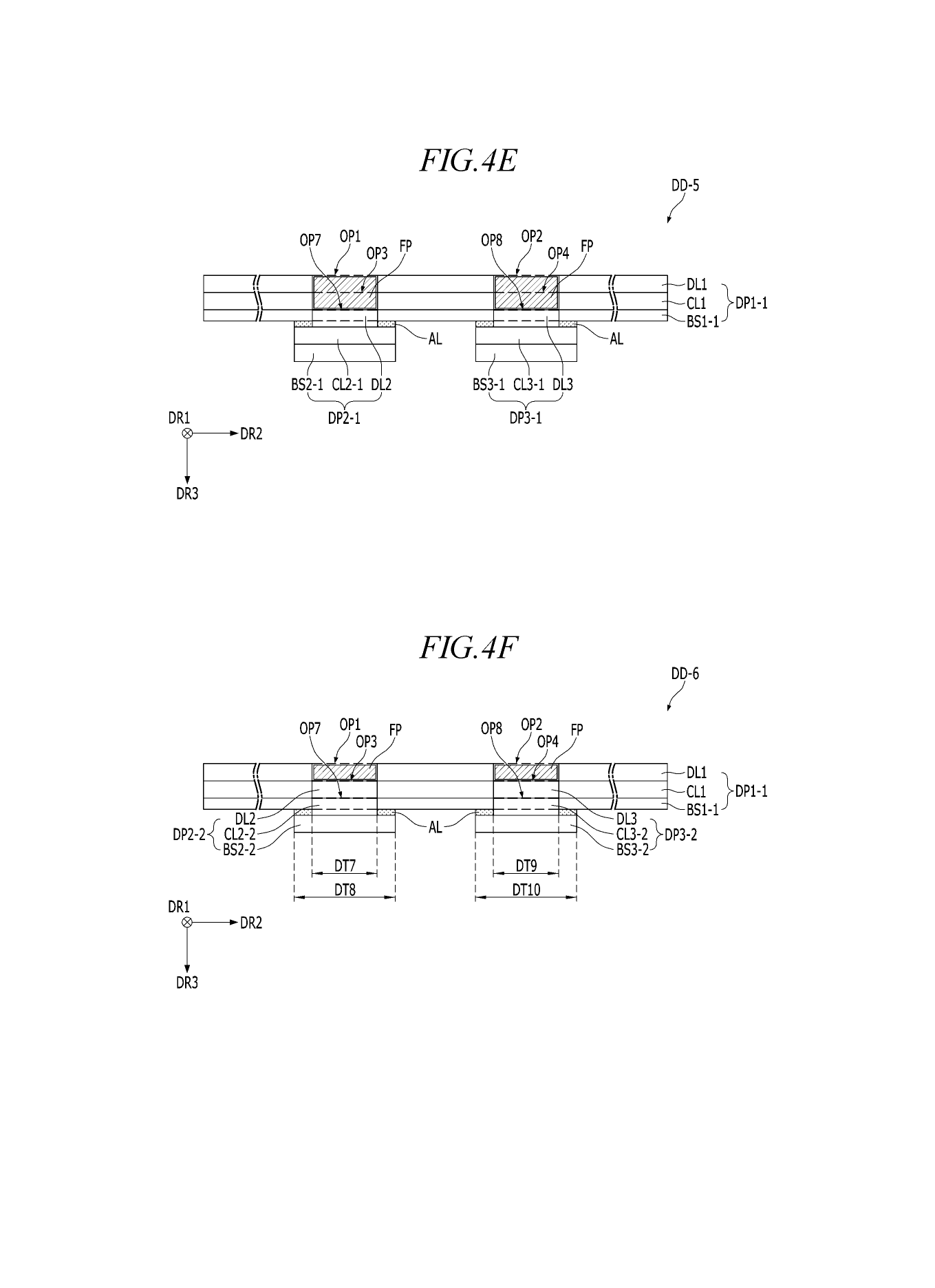

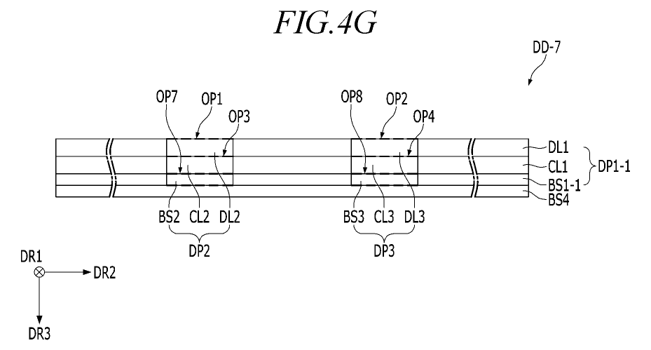

FIG. 4A illustrates a display device DD-1 according to the disclosure. Referring to FIG. 4A, the display device DD-1 may further include an adhesive layer AL. The adhesive layer AL may attach each of the second display panel DP2 and the third display panel DP3 to the first display panel DP1. A portion of the adhesive layer AL may be disposed between the first substrate BS1 of the first display panel DP1 and the second display layer DL2 of the second display panel DP2. Another portion of the adhesive layer AL may be disposed between the first substrate BS1 of the first display panel DP1 and the third display layer DL3 of the third display panel DP3.

FIG. 4B illustrates an embodiment of a display device DD-2 according to the disclosure. Referring to FIG. 4B, the first substrate BS1-1 of a first display panel DP1-1 may define a seventh opening OP7 and an eighth opening OP8 therein. The seventh opening OP7 may overlap the first opening OP1 in the first direction DR1, and the eighth opening OP8 may overlap the second opening OP2 in the first direction DR1.

The display device DD-2 may further include a filling member FP. The filling member FP may be disposed in at least a portion of the first opening OP1, the third opening OP3, and the seventh opening OP7, as well as in at least a portion of the second opening OP2, the fourth opening OP4, and the eighth opening OP8.

FIG. 4C illustrates an embodiment of a display device DD-3 according to the disclosure. Referring to FIG. 4C, the second display layer DL2 may be disposed in at least a portion of the first opening OP1, the third opening OP3, and the seventh opening OP7. The third display layer DL3 may be disposed in at least a portion of the second opening OP2, the fourth opening OP4, and the eighth opening OP8.

The display device DD-3 may further include a filling member FP. The filling member FP may be disposed in at least a portion of the first opening OP1 and the third opening OP3, as well as in at least a portion of the second opening OP2 and the fourth opening OP4.

FIG. 4D illustrates an embodiment of a display device DD-4 according to the disclosure. Referring to FIG. 4D, a third length DT3, which is the length of the second display layer DL2 measured in the second direction DR2, may be smaller than a fourth length DT4, which is the length of the second circuit layer CL2-1 of a second display panel DP2-1 measured in the second direction DR2. Similarly, a fifth length DT5, which is the length of the third display layer DL3 measured in the second direction DR2, may be smaller than a sixth length DT6, which is the length of the third circuit layer CL3-1 of a third display panel DP3-1 measured in the second direction DR2.

The display device DD-4 may further include a filling member FP. The filling member FP may be disposed in at least a portion of the first opening OP1 and the third opening OP3, as well as in at least a portion of the second opening OP2 and the fourth opening OP4.

FIG. 4E illustrates an embodiment of a display device DD-5 according to the disclosure. Referring to FIG. 4E, the display device DD-5 may further include an adhesive layer AL configured to attach each of the second display panel DP2-1 and the third display panel DP3-1 to the first display panel DP1-1. A portion of the adhesive layer AL may be disposed between the first substrate BS1-1 of the first display panel DP1-1 and the second circuit layer CL2-1 of the second display panel DP2-1, and another portion of the adhesive layer AL may be disposed between the first substrate BS1-1 of the first display panel DP1-1 and the third circuit layer CL3-1 of the third display panel DP3-1.

In an embodiment of the disclosure, the second circuit layer CL2-1 of the second display panel DP2-1 may be disposed in at least a portion of the first opening OP1, the third opening OP3, and the seventh opening OP7. The third circuit layer CL3 of the third display panel DP3-1 may be disposed in at least a portion of the second opening OP2, the fourth opening OP4, and the eighth opening OP8.

The display device DD-5 may further include a filling member FP. The filling member FP may be disposed in at least a portion of the first opening OP1 and the third opening OP3, as well as in at least a portion of the second opening OP2 and the fourth opening OP4.

FIG. 4F illustrates an embodiment of a display device DD-6 according to the disclosure. Referring to FIG. 4F, in an embodiment of the disclosure, a seventh length DT7, which is the length of the second circuit layer CL2-2 measured in the second direction DR2, may be smaller than an eighth length DT8, which is the length of the second substrate BS2-2 measured in the second direction DR2. Similarly, a ninth length DT9, which is the length of the third circuit layer CL3-2 measured in the second direction DR2, may be smaller than a tenth length DT10, which is the length of the third substrate BS3-2 measured in the second direction DR2.

In an embodiment of the disclosure, the display device DD-6 may further include an adhesive layer AL configured to attach each of the second display panel DP2-2 and the third display panel DP3-2 to the first display panel DP1-1. A portion of the adhesive layer AL may be disposed between the first substrate BS1 of the first display panel DP1-1 and the second substrate BS2-2 of the second display panel DP2-2. Another portion of the adhesive layer AL may be disposed between the first substrate BS1-1 of the first display panel DP1-1 and the third substrate BS3-2 of the third display panel DP3-2.

The display device DD-6 may further include a filling member FP. The filling member FP may be disposed in at least a portion of the first opening OP1 and the third opening OP3, as well as in at least a portion of the second opening OP2 and the fourth opening OP4.

FIG. 4G illustrates an embodiment of a display device DD-7 according to the disclosure. Referring to FIG. 4G, the display device DD-7 may further include a fourth substrate BS4 and an adhesive layer AL. The fourth substrate BS4 may be disposed below the first display panel DP1-1, the second display panel DP2, and the third display panel DP3. The adhesive layer AL may be disposed on the fourth substrate BS4. The first display panel DP1-1, the second display panel DP2, and the third display panel DP3 may each be disposed on the adhesive layer AL.

While illustrative embodiments of the disclosure have been described above, anyone ordinarily skilled in the art to which the disclosure pertains shall appreciate that there may be a variety of modifications and permutations of the disclosure without departing from the technical ideas and scopes of the disclosure that are defined in the appended claims. Moreover, it shall be appreciated that the disclosed embodiments are not intended to restrict the disclosure thereto and that every technical idea within the appended claims and their equivalents is interpreted to be included in the scope of the disclosure.

What is claimed is:

1. A display device comprising:
a first display panel comprising:
a first substrate comprising a first material; and
a first display layer in which a first opening and a second opening are defined, the first display layer comprising:
a first light-emitting diode;
a second display panel overlapping the first opening, the second display panel comprising:
a second substrate comprising a second material different from the first material; and
a second display layer comprising a second light-emitting diode; and
a third display panel overlapping the second opening, the third display panel comprising:
a third substrate comprising a third material different from the first material; and
a third display layer comprising a third light-emitting diode,
wherein a resolution of each of the second display panel and the third display panel is higher than a resolution of the first display panel,
wherein a first region and a second region are defined in the first substrate,
wherein a first length from the first region to one of the first opening and the second opening, is smaller than a second length from the second region to one of the first opening and the second opening, and
wherein a surface roughness of the first substrate in the first region is greater than a surface roughness of the first substrate in the second region.

2. The display device of claim 1, wherein the first display panel further comprises a first circuit layer disposed between the first substrate and the first display layer,
wherein the first circuit layer comprises:
a first semiconductor pattern disposed above the first substrate and comprising a semiconductor material;
a first gate insulation layer covering the first semiconductor pattern;
a first gate pattern disposed above the first gate insulation layer, wherein at least a portion of the first gate pattern overlaps the first semiconductor pattern;
a first inter-insulation layer covering the first gate pattern;
a first source-drain pattern disposed on the first inter-insulation layer, wherein at least a portion of the first source-drain pattern is electrically connected to the first semiconductor pattern; and
a first via layer covering at least a portion of the first source-drain pattern,
wherein a third opening and a fourth opening are defined in the first circuit layer,
wherein the third opening overlaps the first opening in a first direction, and
wherein the fourth opening overlaps the second opening in the first direction.

3. The display device of claim 2, wherein a portion of the first via layer overlapping the first region of the first substrate is carbonized.

4. The display device of claim 2, further comprising an adhesive layer configured to attach each of the second display panel and the third display panel to the first display panel,
wherein a portion of the adhesive layer is disposed between the first substrate of the first display panel and the second display layer of the second display panel, and another portion of the adhesive layer is disposed between the first substrate of the first display panel and the third display layer of the third display panel.

5. The display device of claim 2, further comprising a filling member comprising a transparent material and disposed in the first opening and the second opening,
wherein a fifth opening is defined in the first via layer, and the fifth opening is defined between the first light-emitting diode and one of the third opening and the fourth opening,
wherein the first display layer further comprises a first pixel defining layer disposed on the first via layer,
wherein a first light-emitting diode opening and a sixth opening are defined in the first pixel defining layer,
wherein the first light-emitting diode is disposed in the first light-emitting diode opening, and
wherein the sixth opening overlaps the fifth opening in the first direction.

6. The display device of claim 2, wherein a seventh opening and an eighth opening are defined in the first substrate,
wherein the seventh opening overlaps the first opening in the first direction, and
wherein the eighth opening overlaps the second opening in the first direction.

7. The display device of claim 6, wherein the second display layer is disposed in at least a portion of the first opening, the third opening, and the seventh opening, and
wherein the third display layer is disposed in at least a portion of the second opening, the fourth opening, and the eighth opening.

8. The display device of claim 6, wherein a second direction intersects the first direction,
wherein the second display panel and the third display panel include a second circuit layer and a third circuit layer, respectively,
wherein a third length of the second display layer measured in the second direction, is smaller than a fourth length of the second circuit layer measured in the second direction, and
wherein a fifth length of the third display layer measured in the second direction, is smaller than a sixth length of the third circuit layer measured in the second direction.

9. The display device of claim 8, further comprising an adhesive layer configured to attach each of the second display panel and the third display panel to the first display panel,
wherein a portion of the adhesive layer is disposed between the first substrate of the first display panel and the second circuit layer of the second display panel, and another portion of the adhesive layer is disposed between the first substrate of the first display panel and the third circuit layer of the third display panel.

10. The display device of claim 6, wherein the second display panel and the third display panel include a second circuit layer and a third circuit layer, respectively,
wherein the second circuit layer of the second display panel is disposed in at least a portion of the first opening, the third opening, and the seventh opening, and
wherein the third circuit layer of the third display panel is disposed in at least a portion of the second opening, the fourth opening, and the eighth opening.

11. The display device of claim 6, wherein a second direction intersects the first direction,
wherein the second display panel and the third display panel include a second circuit layer and a third circuit layer, respectively,
wherein a seventh length of the second circuit layer measured in the second direction, is smaller than an eighth length of the second substrate measured in the second direction, and
wherein a ninth length of the third circuit layer measured in the second direction, is smaller than a tenth length of the third substrate measured in the second direction.

12. The display device of claim 11, further comprising an adhesive layer configured to attach each of the second display panel and the third display panel to the first display panel,
wherein a portion of the adhesive layer is disposed between the first substrate of the first display panel and the second substrate of the second display panel, and another portion of the adhesive layer is disposed between the first substrate of the first display panel and the third substrate of the third display panel.

13. The display device of claim 1, wherein the first material is polyimide (“PI”), and each of the second material and the third material is silicon (Si).

14. The display device of claim 1, further comprising:
a fourth substrate disposed below the first display panel, the second display panel, and the third display panel; and
an adhesive layer disposed on the fourth substrate,
wherein the first display panel, the second display panel, and the third display panel are disposed on the adhesive layer.

15. A head-mounted display comprising:
a display device configured to emit light, the display device comprising:
a first display panel comprising:
a first substrate comprising a first material; and
a first display layer in which a first opening and a second opening are defined, the first display layer comprising:
a first light-emitting diode;
a second display panel overlapping the first opening, the second display panel comprising:
a second substrate comprising a second material different from the first material; and
a second display layer comprising a second light-emitting diode; and
a third display panel overlapping the second opening, the third display panel comprising:
a third substrate comprising a third material different from the first material; and
a third display layer comprising a third light-emitting diode; and
a head-mounted apparatus comprising a frame to which the display device is coupled,
wherein a resolution of each of the second display panel and the third display panel is higher than a resolution of the first display panel.

16. The head-mounted display of claim 15, wherein a first region and a second region are defined in the first substrate,
wherein a first length from the first region to one of the first opening and the second opening is smaller than a second length from the second region to one of the first opening and the second opening, and
wherein a surface roughness of the first substrate in the first region is greater than a surface roughness of the first substrate in the second region.

17. The head-mounted display of claim 15, wherein the first display panel further comprises a first circuit layer disposed between the first substrate and the first display layer,
wherein the first circuit layer comprises:
a first semiconductor pattern disposed above the first substrate and comprising a semiconductor material;
a first gate insulation layer covering the first semiconductor pattern;
a first gate pattern disposed above the first gate insulation layer, wherein at least a portion of the first gate pattern overlaps the first semiconductor pattern;
a first inter-insulation layer covering the first gate pattern;
a first source-drain pattern disposed on the first inter-insulation layer, wherein at least a portion of the first source-drain pattern is electrically connected to the first semiconductor pattern; and
a first via layer covering at least a portion of the first source-drain pattern,
wherein a third opening and a fourth opening are defined in the first circuit layer,
wherein the third opening overlaps the first opening in a first direction,
wherein the fourth opening overlaps the second opening in the first direction, and
wherein a portion of the first via layer overlapping the first region of the first substrate is carbonized.

18. The head-mounted display of claim 17, wherein the display device further comprises a filling member disposed in the first opening and the second opening,
wherein the filling member comprises a transparent material,
wherein a fifth opening is defined in the first via layer, and the fifth opening is defined between the first light-emitting diode and one of the third opening and the fourth opening,
wherein the first display layer further comprises a first pixel defining layer,
wherein a first light-emitting diode opening and a sixth opening defined are in the first pixel defining layer,
wherein the first light-emitting diode is disposed in the first light-emitting diode opening, and
wherein the sixth opening overlaps the fifth opening in the first direction.

19. The head-mounted display of claim 17, wherein a seventh opening and an eighth opening are defined in the first substrate,
wherein the seventh opening overlaps the first opening in the first direction,
wherein the eighth opening overlaps the second opening in the first direction,
wherein the second display layer is disposed in at least a portion of the first opening, the third opening, and the seventh opening, and
wherein the third display layer is disposed in at least a portion of the second opening, the fourth opening, and the eighth opening.

20. An electronic device comprising:
a display device configured to emit light, the display device comprising:
a first display panel comprising:
a first substrate comprising a first material; and
a first display layer in which a first opening and a second opening are defined, the first display layer comprising:
a first light-emitting diode;
a second display panel overlapping the first opening, the second display panel comprising:
a second substrate comprising a second material different from the first material; and
a second display layer comprising a second light-emitting diode; and
a third display panel overlapping the second opening, the third display panel comprising:
a third substrate comprising a third material different from the first material; and
a third display layer comprising a third light-emitting diode,
wherein a resolution of each of the second display panel and the third display panel is higher than a resolution of the first display panel,
wherein a first region and a second region are defined in the first substrate,
wherein a first length from the first region to one of the first opening and the second opening is smaller than a second length from the second region to one of the first opening and the second opening, and
wherein a surface roughness of the first substrate in the first region is greater than a surface roughness of the first substrate in the second region.
